(19) United States
(12) Patent Application Publication
(10) Pub. No.: US 2023/0395452 A1
(43) Pub. Date: Dec. 7, 2023

(54) ELECTRONIC DEVICE AND MANUFACTURING METHOD THEREOF

(71) Applicant: InnoLux Corporation, Miao-Li County (TW)

(72) Inventors: Cheng-Chi WANG, Miao-Li County (TW); Chin-Ming HUANG, Miao-Li County (TW); Yi-Reng CHEN, Miao-Li County (TW)

(21) Appl. No.: 17/811,909

(22) Filed: Jul. 12, 2022

(30) Foreign Application Priority Data
Jun. 6, 2022 (CN) 202210629975.5

(51) Int. Cl. H01L 23/31; H01L 23/00; H01L 21/56

(52) U.S. Cl. CPC H01L 23/3192; H01L 24/20; H01L 24/19; H01L 24/96; H01L 21/561; H01L 21/566; H01L 2924/3512; H01L 2224/2101; H01L 2224/2105; H01L 2224/211; H01L 2224/214; H01L 2224/95001; H01L 2924/3511; H01L 23/3171

(57) ABSTRACT

An electronic device and a manufacturing method thereof are provided. The electronic device includes an electronic unit, a first insulating layer, a second insulating layer and a connecting element. The electronic unit includes a first surface, a second surface opposite to the first surface, and a first side surface connecting the first surface to the second surface. The first insulating layer is disposed on the second surface. The second insulating layer is disposed on the first insulating layer. The second insulating layer includes a third surface, a fourth surface opposite to the third surface, and a second side surface connecting the third surface to the fourth surface. The connecting element is disposed on the second insulating layer and is electrically connected to the electronic unit. The third surface of the second insulating layer is in contact with the second surface of the electronic unit.

### CROSS REFERENCE TO RELATED APPLICATIONS

This application claims priority of China Patent Application No. CN 202210629975.5, filed on Jun. 6, 2022, the entirety of which is incorporated by reference herein.

### TECHNICAL FIELD

Some embodiments of the present disclosure relate to an electronic device and a manufacturing method thereof, and, in particular, to an electronic device including a first insulating layer and a second insulation layer and a manufacturing method thereof.

### BACKGROUND

In general, a packaging process is performed on electronic units, so that the electronic unit may resist pollutants in the external environment, avoid damage to the electronic unit caused by manual operation, achieve a fixed function and/or dissipate heat, so as to improve reliability and/or other electrical properties of the electronic unit.

In current packaging processes, the above advantages are often achieved by disposing a protective layer on the electronic unit. However, in response to consumer demand, the size of electronic units and their components are also gradually being reduced. Directly arranging a protective layer on a small electronic unit may lead to many problems, including insufficient space in the circuit design, frequent unintended disconnection, a tendency to short-circuit, and current leakage.

Therefore, although existing electronic devices and their manufacturing methods have gradually met their intended uses, they have not yet fully met the requirements in all aspects. Therefore, there are still some problems to be overcome with respect to electronic devices and manufacturing methods thereof.

### SUMMARY

In some embodiments, an electronic device is provided. The electronic device includes an electronic unit, a first insulating layer, a second insulating layer and a connecting element. The electronic unit includes a first surface, a second surface opposite to the first surface, and a first side surface connecting the first surface to the second surface. The first insulating layer is disposed on the second surface. The second insulating layer is disposed on the first insulating layer. The second insulating layer includes a third surface, a fourth surface opposite to the third surface, and a second side surface connecting the third surface to the fourth surface. The connecting element is disposed on the second insulating layer and is electrically connected to the electronic unit. The third surface of the second insulating layer is in contact with the second surface of the electronic unit.

In some embodiments, a method for manufacturing an electronic device is provided. The method includes providing a substrate. The substrate includes a plurality of electronic units. The first insulating layer is provided on the substrate. The second insulating layer is provided on the substrate. Wherein, the second insulating layer is in contact with a portion of a surface of the substrate.

The electronic device of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure may be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 to FIG. 6 are respectively cross-section views showing the first electronic device 1 at various stages according to some embodiments of the present disclosure.

FIG. 7 to FIG. 16 are respectively cross-section views showing the second electronic device 2 at various stages according to some embodiments of the present disclosure.

### DETAILED DESCRIPTION

Electronic devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar and/or corresponding reference numerals may be used in different embodiments to designate similar and/or corresponding elements in order to clearly describe the present disclosure. However, the use of these similar and/or corresponding reference numerals is only for the purpose of simply and clearly description of some embodiments of the present disclosure, and does not imply any correlation between the different embodiments and/or structures discussed.

It should be understood that relative terms, such as “lower”, “bottom”, “higher” or “top” may be used in various embodiments to describe the relative relationship of one element of the drawings to another element. It will be understood that if the device in the figures were turned upside down, elements described on the “lower” side would become elements on the “upper” side. The embodiments of the present disclosure may be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second” and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connecting”, “interconnecting”, “bonding” and the like, unless otherwise defined, may refer to two structures in direct contact, or they may refer to two structures that are not in direct contact, there being another structure disposed between the two structures. Terms related to bonding and connection may also include embodiments in which both structures are movable, or both structures are fixed. Furthermore, the terms “electrically connected” or “electrically coupled” include direct and indirect means of electrical connection.

Herein, the terms “about”, “approximately” and “substantially” generally mean within 10%, within 5%, within 3%, within 2%, within 1%, or within 0.5% of a given value or range. The given value is an approximate value, that is, “about”, “approximately”, “substantially” may still be implied without the specific description of “about”, “approximately”, “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 1% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Furthermore, it should be understood that, according to the embodiments of the present disclosure, a width, a thickness, or a height of each element, and a spacing or a distance between elements may be measured by using a scanning electron microscope (SEM), an optical microscope (OM), a film thickness profiler (α-step), ellipsometer, or other suitable methods. In detail, according to some embodiments, a cross-sectional structure image including a component to be measured may be obtained by using the scanning electron microscope, and then the width, the thickness, the height, or the angle of each element, and the spacing or the distance between elements may be measured.

Certain terms may be used throughout the specification and claims in this disclosure to refer to specific elements. A person of ordinary skills in the art should be understood that electronic device manufacturers may refer to the same element by different terms. This disclosure does not intend to distinguish between elements that have the same function but with different terms. In the following description and claims, terms such as “including”, “containing” and “having” are open-ended words, so they should be interpreted as meaning “including but not limited to . . . ”. Therefore, when the terms “including”, “containing” and/or “having” is used in the description of the present disclosure, it designates the presence of corresponding features, regions, steps, operations and/or elements, but does not exclude the presence of one or more corresponding features, regions, steps, operations and/or elements.

It should be understood that, in the following embodiments, features in several different embodiments may be replaced, recombined, and bonded to complete other embodiments without departing from the spirit of the present disclosure. The features of the various embodiments may be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), and the Z-axis direction is the second direction D2 (thickness direction). In some embodiments, the schematic cross-sectional views described herein are schematic views of the XZ plane.

In some embodiments, the electronic device of the present disclosure may include a display device, a lighting device, an antenna device, a sensing device, or a titling device, but the present disclosure is not limited thereto. The electronic device may be a foldable or flexible electronic device. The display device may be a non-self-luminous display device or a self-luminous display device. The antenna device may be a liquid crystal antenna device or a non-liquid crystal antenna device. The sensing device may be a sensing device for sensing capacitance, light, heat, or ultrasonic waves, but the present disclosure is not limited thereto. In the present disclosure, the electronic device may include an electronic unit. The electronic unit is, for example, a known good die (KGD) (that is, a known good wafer), a semiconductor wafer or a diode, but the present disclosure is not limited thereto. The electronic unit may include passive elements and active elements, such as capacitors, resistors, inductors, diodes, transistors, and the like. The diodes may include light emitting diodes or photodiodes. The light emitting diodes may include, for example, organic light emitting diodes (OLEDs), mini light emitting diodes (mini LEDs), micro light emitting diodes (micro LEDs), or quantum dot light emitting diodes (quantum dot LED), but the present disclosure is not limited thereto. The titling device may be, for example, a display titling device or an antenna titling device, but the present disclosure is not limited thereto. It should be noted that, the electronic device may be any arrangement and combination of the foregoing, but the present disclosure is not limited thereto. The present disclosure will be described below with reference to an electronic device including an electronic unit, but the present disclosure is not limited thereto.

In addition, the shape of the electronic device may be rectangular, circular, polygonal, a shape with curved edges, or another suitable shape. The electronic device may have a peripheral system, such as a processing system, a driving system, a control system, a light source system, a shelf system, or the like to support the display device or titling device. It should be noted that, the electronic device may be any arrangement and combination of the foregoing, but the present disclosure is not limited thereto.

It should be appreciated that, in some embodiments, additional processing steps may be provided before, during, and/or after a manufacturing method of an electronic device. In some embodiments, some of the described processing steps may be replaced or omitted, and the order of some of the described processing steps may be interchangeable. Furthermore, it should be understood that some of the described processing steps may be replaced or deleted for other embodiments of the method.

In some embodiments, the manufacturing method of the electronic device of the present disclosure is suitable for a chip first process and a redistribution layer first (RDL first) process. In some embodiments, the manufacturing method of the electronic device of the present disclosure is suitable for a face up process and a face down process. For the convenience of description, in the following, an embodiment which applied in the face down process and the chip first process is taken as an example, but the present disclosure is not limited thereto. In addition, in the present disclosure, the number and size of each element in the drawings are only for description, and are not intended to limit the scope of the present disclosure.

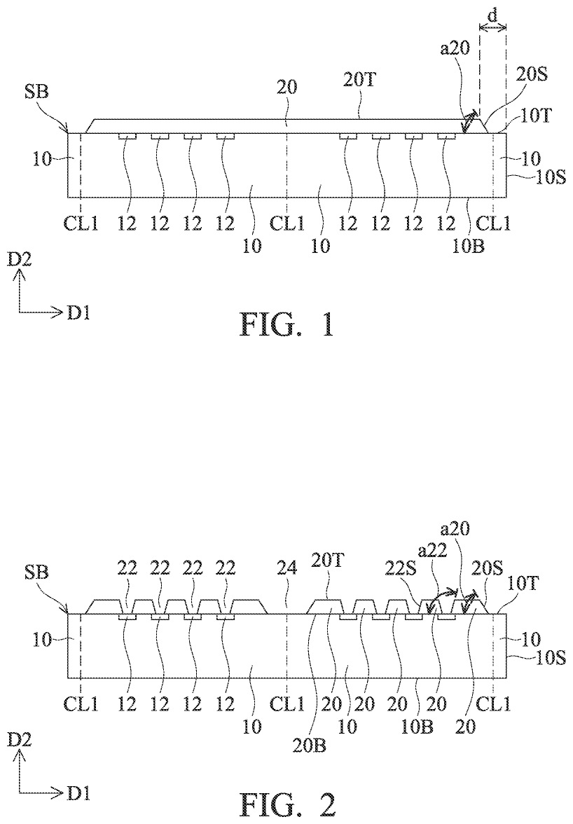

Refer to FIG. 1, which is a schematic cross-sectional view of an electronic device in an intermediate manufacturing stage according to some embodiments of the present disclosure. As shown in FIG. 1, a substrate SB is provided, and the substrate SB includes a plurality of electronic units 10. In some embodiments, the substrate SB may be a wafer such as silicon, a semiconductor-on-insulator (SOI) substrate, other suitable substrates, or combinations of the foregoing, but the present disclosure is not limited thereto. The individual electronic units 10 are isolated from each other by a dashed line CL1, wherein the dashed line CL1 is, for example, a first virtual cutting line CL1. A cutting process will be subsequently performed to separate electronic units 10 and other subsequently formed elements along the first virtual cutting line CL1.

In some embodiments, each of the plurality of electronic units 10 may include light emitting elements such as pixels, light emitting diodes, photodiodes; conductive elements such as metal layers, wires, vias, bonding pads; driving elements such as transistor; functional layers such as insulating layers, interlayer dielectric layers, passivation layers, planarization layers, dielectric materials; other suitable components, or combinations of the foregoing, but the present disclosure is not limited thereto. In some embodiments, the electronic unit 10 may be a die, a chip unit, other suitable units, or combinations of the foregoing, but the present disclosure is not limited thereto. In some embodiments, electronic unit 10 may include a bottom surface 10B (a first surface), a top surface 10T (a second surface) opposite to the bottom surface 10B, and a side surface 10S (a first side surface) connecting the bottom surface 10B to the top surface 10T.

In some embodiments, as shown in FIG. 1, the substrate SB may include at least two electronic units 10, but the present disclosure is not limited thereto. For example, the substrate SB may include any natural number of electronic units 10, wherein the natural number is greater than two. In some embodiments, the electronic units 10 may be arranged in the substrate SB in a matrix manner.

In some embodiments, each of the plurality of electronic units 10 may include bonding pads 12 for electrical connection to other components. In some embodiments, bonding pads 12 may include conductive materials. For example, the conductive material may include metal, metal nitride, semiconductor material, other suitable conductive material, or combinations of the foregoing, but the present disclosure is not limited thereto. In some embodiments, the conductive material may be gold (Au), nickel (Ni), platinum (Pt), palladium (Pd), iridium (Ir), titanium (Ti), chromium (Cr), tungsten (W), aluminum (Al), copper (Cu), molybdenum (Mo), silver (Ag), magnesium (Mg), alloys or compounds thereof, other suitable conductive materials, or combinations of the foregoing, but the present disclosure is not limited thereto. In some embodiments, the conductive material may include transparent conductive oxide (TCO), for example, may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials, or combinations of the foregoing, but the present disclosure is not limited thereto.

In some embodiments, the bonding pads 12 may be formed by using, for example, chemical vapor deposition (CVD), sputtering, resistance heating evaporation, electron beam evaporation, physical vapor deposition (PVD), other suitable deposition processes, or combinations of the foregoing, but the present disclosure is not limited thereto.

In some embodiments, a single electronic unit 10 may include a plurality of bonding pads 12. For example, as shown in FIG. 1, a single electronic unit 10 may include four bonding pads 12, but the present disclosure is not limited thereto. According to electrical requirements, the electronic unit 10 may include any natural number of bonding pads 12. In some embodiments, for convenience of description, FIG. 1 shows that the top surface of the bonding pad 12 is aligned with the top surface 10T of the electronic unit 10, but the present disclosure is not limited thereto. The top surface of the bonding pad 12 may be higher than the top surface 10T of the electronic unit 10.

As shown in FIG. 1, in some embodiments, a first insulating layer 20 is provided on the substrate SB. In some embodiments, the first insulating layer 20 is provided on the top surface 10T of the electronic unit 10, such that the bottom surface 20B of the first insulating layer 20 is in contact with the top surface 10T of the electronic unit 10. In some embodiments, the first insulating layer 20 may be formed on the electronic unit 10 by, for example, chemical vapor deposition (CVD), sputtering, resistance heating evaporation, electron beam evaporation, other suitable deposition processes, or combinations of the foregoing.

In some embodiments, the first insulating layer 20 may be or may include an organic material, an inorganic material, other suitable insulating materials, or combinations of the foregoing, but the present disclosure is not limited thereto. In some embodiments, the first insulating layer 20 may be or may include a polymer-based dielectric film such as an organic polymer film. In some embodiments, the first insulating layer 20 may be or may include Ajinomoto build-up film (ABF), epoxy resin, silicone resin, benzocyclobutene (BCB), polyimide (PI) such as photosensitive polyimide (PSPI), polybenzoxazole (PBO), oxides such as silicon oxide (SiOₓ), nitrides such as silicon nitride (SiNₓ), oxynitrides such as silicon oxynitride (SiOₓN_{y}), other suitable build-up materials, other suitable insulating material, or combinations of the foregoing, but the present disclosure is not limited thereto. In some embodiments, the first insulating layer 20 may be or may include a molding material.

In some embodiments, the side surface 20S of the first insulating layer 20 are spaced apart from the outermost side surface 10S of the plurality of electronic units 10 with a distance d. In detail, please refer to FIG. 1, which is a schematic cross-sectional view, and the distance d is the width from the bottom of the side surface 20S of the first insulating layer 20 to the outermost side surface 10S of the plurality of electronic units 10 in the first direction D1. In some embodiments, the side surface 20S of the first insulating layer 20 is not aligned with the outermost side surface 10S of the electronic unit 10 in the first direction D1. In some embodiments, the area of the bottom surface 20B of the first insulating layer 20 is smaller than the area of the top surface 10T of the plurality of electronic units 10. In other words, the projection of the first insulating layer 20 on the top surface 10T of the plurality of electronic units 10 may fall within the top surface 10T of the plurality of electronic units 10. In some embodiments, the difficulty of the subsequently performed first cutting process may be reduced by disposing the first insulating layer 20 with a smaller area than the top surface 10T of the plurality of electronic units 10, thus the process window of the first cutting process may be improved, but the present disclosure is not limited thereto.

In some embodiments, the side surface 20S of the first insulating layer 20 is an inclined side surface. In some embodiments, there is an angle a20 between the side surface 20S of the first insulating layer 20 and the bottom surface 20B of the first insulating layer 20. In some embodiments, the angle a20 may be greater than or equal to about 45 degrees and less than about 90 degrees. For example, the angle a20 may be 45 degrees, 50 degrees, 55 degrees, 60 degrees, 65 degrees, 70 degrees, 75 degrees, 80 degrees, 85 degrees, 89 degrees, or any value or range of values between the foregoing values. In some embodiments, since the side surface 20S of the first insulating layer 20 has the angle a20, it is beneficial to improve the adhesion and/or reliability between the components disposed above the first insulating layer 20 and the first insulating layer 20.

Refer to FIG. 2, which is a schematic cross-sectional view of an electronic device in an intermediate manufacturing stage according to some embodiments of the present disclosure. As shown in FIG. 2, the first insulating layer 20 is patterned to form first openings (or vias) 22, 24 and expose a portion of the top surface 10T of the electronic unit 10. In some embodiments, a corresponding patterning process may be selected according to the material of the first insulating layer 20. For example, when the first insulating layer 20 is a photoresist material, the first insulating layer 20 may be patterned using an exposure process and a development process. For example, when the first insulating layer 20 is a non-photoresist material, the first insulating layer 20 may be patterned using a laser drilling process, or a photoresist pattern may be additionally disposed on the first insulating layer 20 to pattern the first insulating layer 20. Other suitable manufacturing methods may also be used, but the present disclosure is not limited thereto.

In some embodiments, the first insulating layer 20 may be patterned according to the location of the bonding pads 12 on the electronic unit 10. For example, each of the plurality of bonding pads 12 may correspond to one first opening 22, but the present disclosure is not limited thereto. In some embodiments, along the first direction D1, the width of the first opening 24 between adjacent electronic units 10 may be greater than the width of the first opening 22. Therefore, when the subsequent first cutting process is performed, it is easier to separate the adjacent electronic units 10. As shown in FIG. 2, the first opening 22 may have an angle a22. In some embodiments, angle a22 may be greater than or equal to about 90 degrees and less than about 180 degrees. For example, the angle a22 may be 90 degrees, 100 degrees, 110 degrees, 120 degrees, 130 degrees, 140 degrees, 150 degrees, 160 degrees, 170 degrees, 179 degrees, or any value or range of values between the foregoing values. In some embodiments, the angle a22 may be adjusted by adjusting the process parameters of the patterning process.

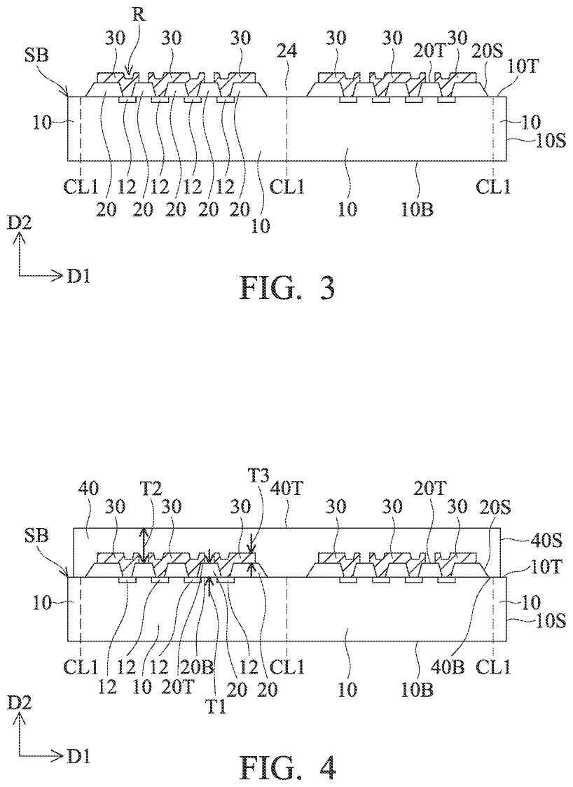

Refer to FIG. 3, which is a schematic cross-sectional view of an electronic device in an intermediate manufacturing stage according to some embodiments of the present disclosure. As shown in FIG. 3, a first conductive layer 30 is provided on the first insulating layer 20. In some embodiments, the material and formation method of the first conductive layer 30 may be the same as or different from the material and formation method of the bonding pad 12. In some embodiments, the first conductive layer 30 may be conformally formed on the first insulating layer 20 and the first conductive layer 30 extends into the first openings 22 and 24. Next, the first conductive layer 30 may be patterned to expose a portion of the top surface 10T of the electronic unit 10 and a portion of the side surface 20S and the top surface 20T of the first insulating layer 20. For example, the first conductive layer 30 is conformally disposed and extends into the first openings 22 and 24. According to some embodiments, the top surface of the first conductive layer 30 corresponding to the first openings 22 and 24 may have a recess R. Further, in the second direction D2, the top surface of the first conductive layer 30 corresponding to the first openings 22 and 24 is higher than the top surface 20T of the first insulating layer 20, and the top surface of the first conductive layer 30 corresponding to the first openings 22 and 24 is lower than the top surface of the first conductive layer 30 corresponding to the first insulating layer 20. The first conductive layer 30 described in the present disclosure may be a single layer conductive material or a multi-layer conductive material, and the first conductive layer 30 may include copper, titanium, aluminum, molybdenum, indium tin oxide, other suitable materials, or combinations of the foregoing, but the present disclosure is not limited thereto.

In some embodiments, the patterned first conductive layer 30 may correspond to one of the plurality of first openings 22 of the first insulating layer 20. In other embodiments, the patterned first conductive layer 30 may correspond to the several first openings 22 of the plurality of first openings 22 of the first insulating layer 20. For example, the patterned first conductive layer 30 may correspond to the two first openings 22, but the present disclosure is not limited thereto. The patterned first conductive layer 30 may correspond to any natural number of the first openings 22, so as to improve the fan-out effects and/or the fan-out range of the first conductive layer 30. The improved fan-out effects may include increased number of elements bonding to other elements and increased bonding ability, and the improved fan-out range means that the fan-out area is increased to avoid insufficient space during circuit design, but the present disclosure is not limited thereto. In some embodiments, the first conductive layer 30 may be disposed between the first insulating layer 20 and the subsequently formed second insulating layer 40 (referring to FIG. 4). The first conductive layer 30 is electrically connected to the bonding pad 12 of the electronic unit 10 through one of the plurality of first openings 22.

In other embodiments, a seed layer (not shown) may be conformally formed on the first insulating layer 20 and formed in the first openings 22 and 24, and then a metal layer may be formed on the seed layer. The materials of the seed layer and the metal layer include, for example, titanium and copper, but the present disclosure is not limited thereto. Next, the metal layer and the seed layer are patterned to remove a portion of the metal layer and to remove a portion of the seed layer, thereby exposing a portion of the top surface 10T of the electronic unit 10.

Refer to FIG. 4, which is a schematic cross-sectional view of an electronic device in an intermediate manufacturing stage according to some embodiments of the present disclosure. As shown in FIG. 4, a second insulating layer 40 is provided on the substrate SB (as shown in FIG. 1). Specifically, the second insulating layer 40 is formed on the top surface 10T of the electronic unit 10, the top surface 20T and the side surface 20S of the first insulating layer 20, the first opening 24 and the first conductive layer 30. In some embodiments, the second insulating layer 40 may include a bottom surface 40B (a third surface), a top surface 40T (a fourth surface) opposite to the bottom surface 40B, and side surface 40S (a second side surface). In some embodiments, the top surface 40T of the second insulating layer 40 is farer away from the electronic unit 10 than the bottom surface 40B of the second insulating layer 40.

In some embodiments, the material and formation method of the second insulating layer 40 may be the same or different from those of the first insulating layer 20. In some embodiments, since the materials of the first insulating layer 20 and the second insulating layer 40 are different, the first insulating layer 20 and the second insulating layer 40 may have an interface therebetween. In the following description, an embodiment in which the first insulating layer 20 and the second insulating layer 40 are different is taken as an example.

In some embodiments, as shown in FIG. 4, the first insulating layer 20 may have a first thickness T1, and the second insulating layer 40 may have a second thickness T2. In some embodiments, the first thickness T1 of the first insulating layer 20 is a distance between the bottom surface 20B and the top surface 20T of the first insulating layer 20 in the second direction D2. In some embodiments, the second thickness T2 of the second insulating layer 40 is a distance between the top surface 20T of the first insulating layer 20 and the top surface 40T of the second insulating layer 40 in the second direction D2.

In some embodiments, the first thickness T1 of the first insulating layer 20 may be greater than or equal to about 2 um and less than or equal to about 10 um. For example, the first thickness T1 may be 2 um, 3 um, 4 um, 5 um, 6 um, 7 um, 8 um, 9 um, 10 um, or any value or range of values between the foregoing values. In some embodiments, the second thickness T2 of the second insulating layer 40 may be greater than or equal to about 13 um and less than or equal to about 50 um. For example, the second thickness T2 may be 13 um, 15 um, 20 um, 25 um, 30 um, 35 um, 40 um, 45 um, 50 um, or any value or range of values between the foregoing values. In some embodiments, the first thickness T1 of the first insulating layer 20 may be less than the second thickness T2 of the second insulating layer 40. In some embodiments, the ratio (T1/T2) of the first thickness T1 of the first insulating layer 20 to the second thickness T2 of the second insulating layer 40 may be greater than or equal to about 0.02 and less than or equal to about 0.85. For example, the ratio (T1/T2) may be 0.02, 0.04, 0.08, 0.1, 0.2, 0.3, 0.4, 0.5, 0.6, 0.7, 0.75, 0.8, 0.85, or any value or range of values between the foregoing values.

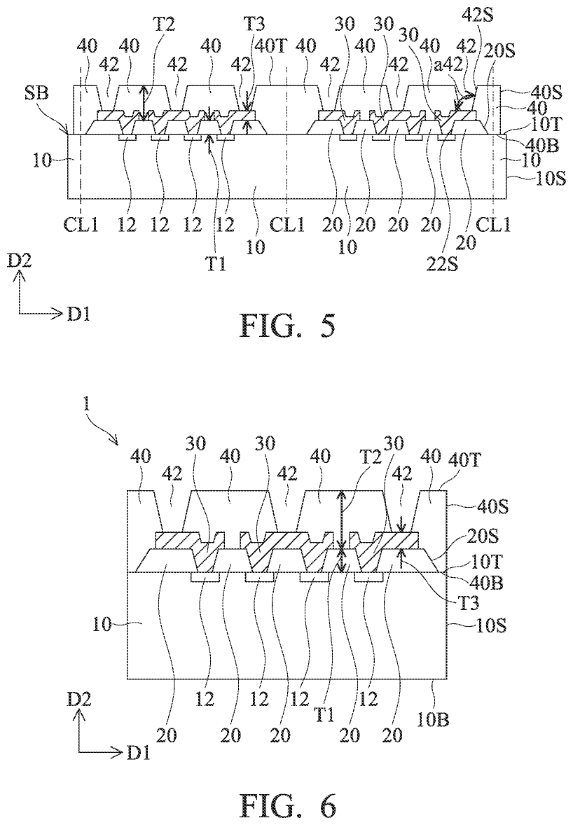

In some embodiments, since the first thickness T1 of the first insulating layer 20 may be less than the second thickness T2 of the second insulating layer 40, bonding pads 12 may be gradually fanned-out by stacking the first insulating layer 20 and the second insulating layer 40. For example, the bonding pad 12 may be initially fanned-out through the first opening 22 of the first insulating layer 20, and the bonding pad 12 may be further fanned-out through the second opening 42 of the second insulating layer 40 (referring to subsequent FIG. 5), thereby improving the fan-out effects and/or the fan-out range. In other embodiments, the electronic device may further provide another insulating layer with openings between the top surface 10T of the electronic unit 10 and the subsequently formed connecting element 60 (referring to the subsequent FIG. 13), so as to improve the fan-out effects and/or fan-out range.

It should be noted that, since the first insulating layer 20 and the second insulating layer 40 may together serve as the protective layer of the electronic unit 10, the electronic unit 10 may be sufficiently protected from damage. Furthermore, by sequentially disposing the first insulating layer 20 and the second insulating layer 40 on the electronic unit 10, the problem of easy cracking and/or edge warping may be reduced during subsequent cutting processes of a single protective layer. In addition, since the present disclosure disposes the first insulating layer 20 and the second insulating layer 40 by stacking the first insulating layer 20 and the second insulating layer 40, the problem that it is difficult to accurately form openings passing through the single insulating layer in the thick single insulating layer may be avoided.

It should also be noted that, as shown in FIG. 3 and FIG. 4, since the patterned first conductive layer 30 exposes a portion of the top surface 10T of the electronic unit 10, the bottom surface 40B of the second insulating layer 40 is in direct contact with the top surface 10T of the plurality of the electronic units 10, so as to improve the reliability of the subsequent cutting process. For example, since there are fewer components intersecting with the subsequently described first virtual cutting line CL1, the problem of uneven cutting edges, cracking and/or warping after cutting along the first virtual cutting line CL1 may be reduced.

In some embodiments, as shown in FIG. 4, the second insulating layer 40 is in direct contact with the side surface 20S of the first insulating layer 20. In some embodiments, since the inclined side surface 20S of the first insulating layer 20 has the above-mentioned angle a20, the first insulating layer 20 and the second insulating layer 40 may be more easily bonded. Furthermore, when the materials of the first insulating layer 20 and the second insulating layer 40 are different, the angle a20 may disperse the stress between the heterojunctions of the first insulating layer 20 and the second insulating layer 40 and/or may increase the reliability of the heterojunction between the first insulating layer 20 and the second insulating layer 40.

In some embodiments, the coefficient of thermal expansion (CTE) of the first insulating layer 20 and the second insulating layer 40 may be the same or different. In some embodiments, the thermal expansion coefficient of the first insulating layer 20 and/or the second insulating layer 40 may be greater than or equal to about 3 ppm/K to less than or equal to about 60 ppm/K. For example, the thermal expansion coefficient of the first insulating layer 20 and/or the second insulating layer 40 may be 3 ppm/K, 5 ppm/K, 10 ppm/K, 15 ppm/K, 20 ppm/K, 25 ppm/K, 30 ppm/K, 35 ppm/K, 40 ppm/K, 45 ppm/K, 50 ppm/K, 55 ppm/K, 60 ppm/K, or any value or range of values between the foregoing values. In some embodiments, when the thermal expansion coefficients of the first insulating layer 20 and the second insulating layer 40 are different, the warping degree of the electronic device may be reduced. In some embodiments, the thermal expansion coefficient of the first insulating layer 20 is smaller than the thermal expansion coefficient of the second insulating layer 40, so the effect of reducing the warping of the electronic device may be achieved, but the present disclosure is not limited thereto.

In some embodiments, the first insulating layer 20 and the second insulating layer 40 may be reverse warping layers to each other. In other words, because the warping directions of the first insulating layer 20 and the second insulating layer 40 are different, the warping phenomenon may be compensated with each other, thereby reducing the warping degree of the electronic device. For example, the first insulating layer 20 may be an insulating layer that warps upward toward the second direction D2 (opening upward), and the second insulating layer 40 may be an insulating layer that warps downward away from the second direction D2 (opening downward). Therefore, when a combination of the first insulating layer 20 and the second insulating layer 40 is provided, the combination may be able to counteract the warping.

In some embodiments, the Young's modulus of the first insulating layer 20 and/or the second insulating layer 40 may be greater than or equal to about 1000 MPa to less than or equal to about 20000 MPa. For example, the Young's modulus of the first insulating layer 20 and/or the second insulating layer 40 may be 1000 MPa, 2000 MPa, 4000 MPa, 6000 MPa, 8000 MPa, 10000 MPa, 12000 MPa, 14000 MPa, 16000 MPa, 18000 MPa, 20000 MPa, any value or range of values between the foregoing values. In some embodiments, the Young's modulus of the first insulating layer 20 is smaller than the Young's modulus of the second insulating layer 40. Therefore, the second insulating layer 40 formed on the top surface 10T of the electronic unit 10, the top surface 20T and the side surface 20S of the first insulating layer 20, the first opening 24, and the first conductive layer 30 may avoid or reduce the risk of damage to the electronic unit 10, the first insulating layer 20 and/or the first conductive layer 30 from being scratched or damaging, but the present disclosure is not limited thereto.

In some embodiments, since the water-resistance and the oxygen-resistance of the second insulating layer 40 may be greater than those of the first insulating layer 20, the water-resistance and the oxygen-resistance of the electronic device of the present disclosure may be improved by disposing the second insulating layer 40. In some embodiments, since the hardness of the second insulating layer 40 may be greater than the hardness of the first insulating layer 20, the hardness of the electronic device of the present disclosure may be improved by disposing the second insulating layer 40. In these embodiments, even though the water-resistance, the oxygen-resistance and/or hardness of the first insulating layer 20 may be slightly lower than those of the second insulating layer 40, various properties of the electronic device may be effectively improved by the combination of the first insulating layer 20 and the second insulating layer 40. Wherein the first insulating layer 20 may be precisely and easily formed on the electronic unit 10 and helps to form the first opening 22.

In some embodiments, since the first thickness T1 of the first insulating layer 20 is less than the second thickness T2 of the second insulating layer 40, the first insulating layer 20 may include a PSPI which is easier to be precisely patterned, and the second insulating layer 40 may include ABF. Thus, the fan-out effects and/or the fan-out range may be improved by adjusting the thickness ratio and materials of the first insulating layer 20 and the second insulating layer 40.

Refer to FIG. 5, which is a schematic cross-sectional view of an electronic device in an intermediate manufacturing stage according to some embodiments of the present disclosure. As shown in FIG. 5, the second insulating layer 40 is patterned to form the second openings 42 and expose the top surface of the first conductive layer 30. In some embodiments, the second opening 42 may have an angle a42. In some embodiments, the angle a42 may be greater than or equal to 90 degrees and less than 180 degrees. For example, the angle a42 may be 90 degrees, 100 degrees, 110 degrees, 120 degrees, 130 degrees, 140 degrees, 150 degrees, 160 degrees, 170 degrees, 179 degrees, or any value or value range between the foregoing values. In some embodiments, the angle a42 may be adjusted by adjusting the process parameters of the patterning process.

In some embodiments, the angle a22 of one of the plurality of first openings 22 is different from the angle a42 of one of the plurality of second openings 42. In some embodiments, the angle a22 of the first opening 22 is greater than the angle a42 of the second opening 42, and thus, for example, the heat energy generated by the electronic unit 10 may be quickly dissipated, but the present disclosure is not limited thereto.

In some embodiments, the roughness of the first sidewall 22S of one of the plurality of first openings 22 may be less than the roughness of the second sidewall 42S of one of the plurality of second openings 42. In the present disclosure, roughness may be surface roughness, and it may be measured by, for example, arithmetic mean roughness (Ra), maximum height roughness (Ry), ten-point mean roughness (Rz), another similar measure, or combinations of the foregoing. In some embodiments, since the first thickness T1 of the first insulating layer 20 may be less than the second thickness T2 of the second insulating layer 40, the thickness of the conductive component (for example, the first conductive layer 30) disposed in the first opening 22 of the first insulating layer 20 may be less than the thickness of the conductive component (for example, subsequently formed connecting element 60) disposed in the second openings 42 of the second insulating layer 40. Therefore, when the roughness of the first sidewall 22S of the first opening 22 is relatively small and has a relatively smooth sidewall, it may help to accurately form the first conductive layer 30 in the first opening 22 and improve the reliability of the first conductive layer 30. In addition, since the first thickness T1 of the first insulating layer 20 is less than the second thickness T2 of the second insulating layer 40, the accuracy of the formation of the first opening 22 is greater than that of the second opening 42.

On the other hand, when the roughness of the second sidewall 42S of the second opening 42 is relatively large and has a relatively uneven sidewall, the frictional force of the rough sidewall may help to form the connecting element 60 with greater thickness and/or greater width in the second opening 42, thereby improving the reliability of the connecting element 60. For example, the reliability of formation of the connecting element 60 by the subsequent electroplating process may be improved.

In some embodiments, at least one of the plurality of first openings 22 and at least one of the plurality of second openings 42 do not overlap in the normal direction (that is, the second direction D2) of the electronic unit 10, Therefore, the fan-out effects and/or the fan-out range may be improved or the risk of cracking of the metal layer of the electronic device may be reduced, but the present disclosure is not limited thereto. In other embodiments, each of the plurality of first openings 22 and none of the second openings 42 overlap in the normal direction (that is, the second direction D2) of the electronic unit 10. In some embodiments, at least one of the plurality of first openings 22 and at least one of the plurality of second openings 42 overlap in the normal direction (that is, the second direction D2) of the electronic unit 10, thereby improving the process window for the patterning process of the second insulating layer 40. In other embodiments, each of the plurality of first openings 22 and each of the plurality of second openings 42 overlap in the normal direction (that is, the second direction D2) of the electronic unit 10.

In some embodiments, following the above, a first cutting process may be performed to cut the substrate SB, so that the plurality of electronic units 10 is separated into a plurality of first electronic devices. In some embodiments, the first cutting process may include a blade saw process, a die break cutting process, a laser cutting process, other suitable cutting processes, or combinations of the foregoing. As shown in FIG. 5, the first cutting process may be cut along the first virtual cutting line CL1.

Refer to FIG. 6, which is a schematic cross-sectional view of the first electronic device 1 after performing the first cutting process according to some embodiments of the present disclosure. In some embodiments, the first electronic device 1 may be a known good die (KGD), and the first electronic device 1 may include a first conductive layer 30 that may be used as a redistribution layer of a wafer level package. As shown in FIG. 6, after performing the first cutting process, the side surface 10S of the electronic unit 10 of the first electronic device 1 is aligned with the side surface 40S of the second insulating layer 40, so that the second insulating layer 40 protects the electronic unit 10 of the first electronic device 1. That is, in the first direction D1, the distance between the side surface 10S of the electronic unit 10 and the side surface 40S of the second insulating layer 40 is less than or equal to 5 micrometers. The alignment design of the side surface 10S of the electronic unit 10 and the side surface 40S of the second insulating layer 40 is beneficial to improve the quality of subsequent process.

In addition, it should be understood that some elements of the first electronic device 1 may be omitted in FIG. 6, and some elements are schematically shown in FIG. 6 for clarity. In some embodiments, additional components may be added to the first electronic device 1. In other embodiments, some components of the first electronic device 1 described above may be replaced or omitted.

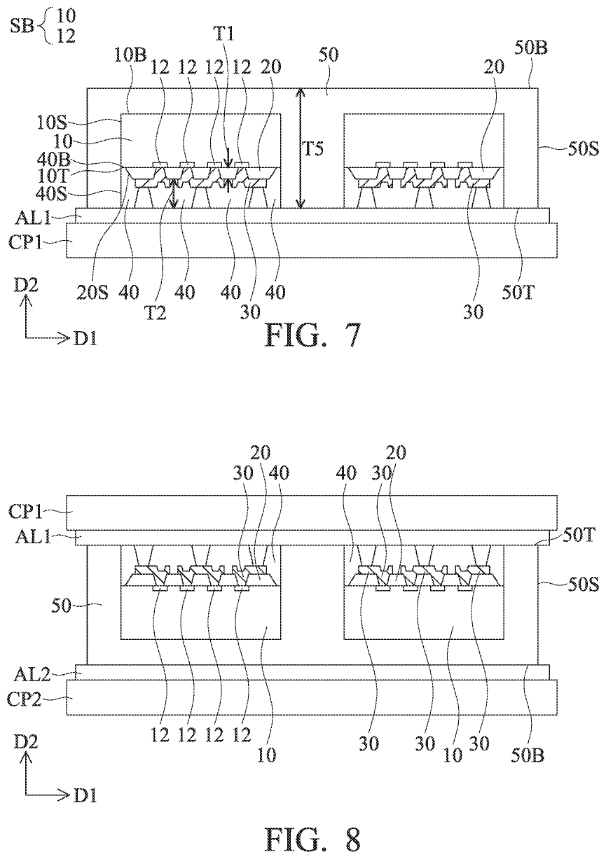

Referring to FIG. 7, it shows a schematic cross-sectional view of the second electronic device 2 in an intermediate manufacturing stage according to some embodiments of the present disclosure. As shown in FIG. 7, a plurality of first electronic devices 1 is provided on the first carrier board CP1. For convenience of description, FIG. 7 shows that two first electronic devices 1 are provided on the first carrier board CP1, but the present disclosure is not limited thereto.

In detail, in some embodiments, as shown in FIG. 7, a first carrier board CP1 is provided, and a first adhesive layer AL1 is disposed on the first carrier board CP1. In some embodiments, the first carrier board CP1 may be or may include a wafer, chip, glass, quartz, sapphire, ceramic, polyimide (PI), polycarbonate (PC), polyethylene terephthalate (PET) carrier board, a polypropylene (PP) carrier board, a temporary carrier board, other suitable carrier boards, or combinations of the foregoing, but the present disclosure is not limited thereto.

In some embodiments, the first adhesive layer AL1 may serve as a peeling layer or a releasing layer. In some embodiments, the first adhesive layer AL1 may be or may include a thermal release adhesive layer, an Ultra-Violet (UV) adhesive layer, a light-to-heat conversion (LTHC) adhesive layer, or other suitable split type adhesive layers, or combinations of the foregoing, but the present disclosure is not limited thereto. In some embodiments, the first adhesive layer AL1 may be formed by a coating process or other suitable forming process. Next, the first electronic device 1 as shown in FIG. 6 is turned upside down along the second direction D2, so that the top surface 40T of the second insulating layer 40 of the first electronic device 1 is in direct contact and bonded with the first adhesive layer AL1.

As shown in FIG. 7, in some embodiments, a third insulating layer 50 is provided on the plurality of first electronic devices 1. In some embodiments, the third insulating layer 50 may surround the electronic unit 10 in the first electronic device 1. For example, the third insulating layer 50 may surround the side surface 10S and the bottom surface 10B of the electronic unit 10. In some embodiments, the third insulating layer 50 may be disposed on the first adhesive layer AL1 and between adjacent first electronic units 10. In some embodiments, the third insulating layer 50 may be disposed on the side surface 40S of the second insulating layer 40, the side surface 10S of the electronic unit 10, and the bottom surface 10B of the electronic unit 10. In some embodiments, the third insulating layer 50 may expose a portion of the side surface 40S of the second insulating layer 40 and/or a portion of the side surface 10S of the electronic unit 10. The alignment design of the side surface 10S of the electronic unit 10 and the side surface 40S of the second insulating layer 40 may reduce, for example, the risk of cracking of the side surface 10S, the side surface 40S and the third insulating layer 50, but the present disclosure is not limited thereto.

In some embodiments, the third insulating layer 50 may be or may include organic materials, inorganic materials, other suitable packaging materials, or combinations of the foregoing, but the present disclosure is not limited thereto. In some embodiments, the aforementioned inorganic material may include silicon nitride, silicon oxide, silicon oxynitride, aluminum oxide, other suitable materials, or combinations of the foregoing, but the present disclosure is not limited thereto. In some embodiments, the aforementioned organic materials may include epoxy resins, silicone resins, acrylic resins, other suitable materials, or combinations of the foregoing, but the present disclosure is not limited thereto. For example, the aforementioned acrylic resin may include polymethylmethacrylate (PMMA), benzocyclobutene (BCB), polyimide, polyester, polydimethylsiloxane (PDMS), and polyfluoroalkoxy (PFA). In some embodiments, the third insulating layer 50 may include ABF. In some embodiments, the third insulating layer 50 may be a transparent, semi-transparent, or opaque material.

In some embodiments, as shown in FIG. 7, the third insulating layer 50 may have a fifth thickness T5. In some embodiments, the fifth thickness T5 may be a distance between the top surface 50T of the third insulating layer 50 and the bottom surface 50B of the third insulating layer 50. In some embodiments, the fifth thickness T5 of the third insulating layer 50 may be greater than the second thickness T2 of the second insulating layer 40. In some embodiments, the fifth thickness T5 of the third insulating layer 50 may be greater than the first thickness T1 of the first insulating layer 20. In some embodiments, the fifth thickness T5 of the third insulating layer 50 may be greater than the sum of the second thickness T2 of the second insulating layer 40 and the first thickness T1 of the first insulating layer 20.

Referring to FIG. 8, it shows a schematic cross-sectional view of the second electronic device 2 in an intermediate manufacturing stage according to some embodiments of the present disclosure. In some embodiments, as shown in FIG. 8, a second carrier board CP2 is provided, and a second adhesive layer AL2 is disposed on the second carrier board CP2. In some embodiments, the material of the second carrier board CP2 and the material of the first carrier board CP1 may be the same or different. In some embodiments, the material and formation method of the second adhesive layer AL2 and the material and formation method of the first adhesive layer AL1 may be the same or different. Next, the structure shown in FIG. 7 is turned upside down along the second direction D2, so that the bottom surface 50B of the third insulating layer 50 is in direct contact and bonded with the second adhesive layer AL2.

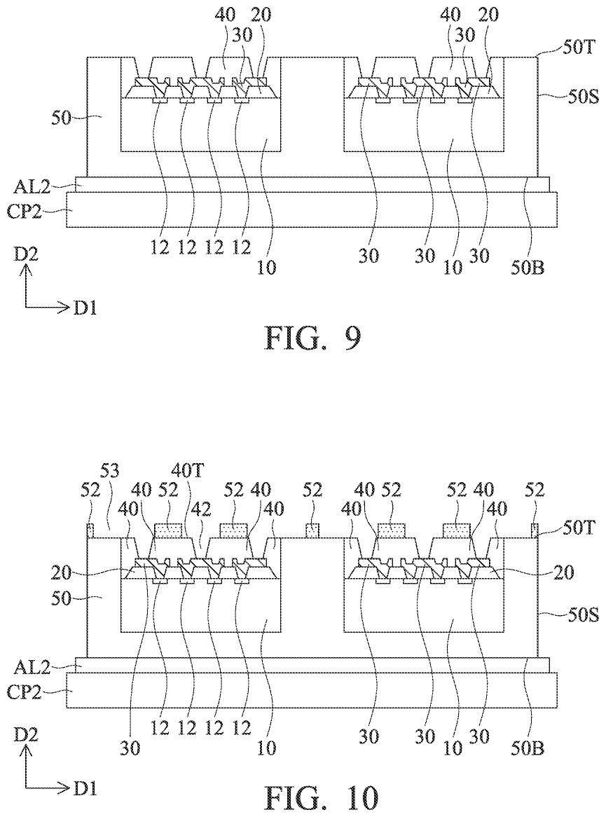

Referring to FIG. 9, it shows a schematic cross-sectional view of the second electronic device 2 in an intermediate manufacturing stage according to some embodiments of the present disclosure. In some embodiments, as shown in FIG. 9, according to the material of the first adhesive layer AL1, a corresponding splitting process may be used to release or remove the first adhesive layer AL1 and the first carrier board CP1 to expose the top surface 50T of the third insulating layer 50.

Referring to FIG. 10, it shows a schematic cross-sectional view of the second electronic device 2 in an intermediate manufacturing stage according to some embodiments of the present disclosure. In some embodiments, as shown in FIG. 10, the first photoresist 52 is formed on the top surface 50T of the third insulating layer 50 and the top surface 40T of the second insulating layer 40. In some embodiments, the first photoresist 52 may be formed by a spin coating process, a chemical vapor deposition process, a physical vapor deposition process, an atomic layer deposition (ALD) process, a high-density plasma CVD (HDP-CVD) process, other suitable methods, or combinations of the foregoing, but the present disclosure is not limited thereto. In some embodiments, the first photoresist 52 may be a dry film photoresist. In some embodiments, the first photoresist 52 may have openings 53 corresponding to the second openings 42 of the second insulating layer 40, in order to expose at least a portion of the top surface of the first conductive layer 30. In some embodiments, one opening 53 of the first photoresist 52 may correspond to one of second openings 42 of the second insulating layer 40, but the present disclosure is not limited thereto.

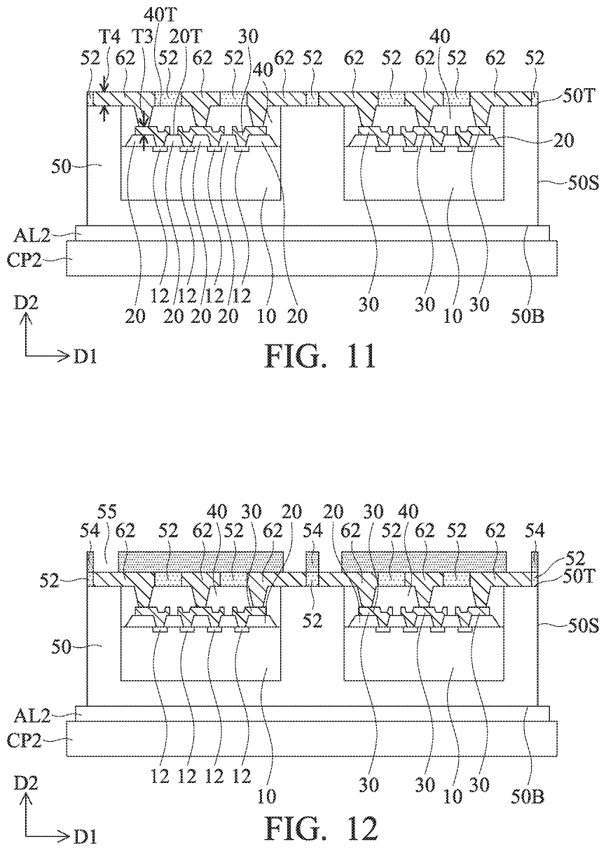

Referring to FIG. 11, it shows a schematic cross-sectional view of the second electronic device 2 in an intermediate manufacturing stage according to some embodiments of the present disclosure. In some embodiments, the second conductive layer 62 is disposed in the opening 53 of the first photoresist 52. In some embodiments, the second conductive layer 62 may be disposed on the top surface 50T of the third insulating layer 50 and the top surface 40T of the second insulating layer 40. In some embodiments, a portion of the second conductive layer 62 is in contact with the top surface 50T of the third insulating layer 50. In some embodiments, the second conductive layer 62 may include a conductive material. For example, the conductive material may include metal, metal nitride, semiconductor material, or combinations of the foregoing, or any other suitable conductive material, but the present disclosure is not limited thereto. In some embodiments, the conductive material may be gold (Au), nickel (Ni), platinum (Pt), palladium (Pd), iridium (Ir), titanium (Ti), chromium (Cr), tungsten (W), Aluminum (Al), copper (Cu), molybdenum (Mo), silver (Ag), magnesium (Mg), alloys or compounds thereof, other suitable conductive materials, or combinations of the foregoing, but the present disclosure is not limited thereto. In some embodiments, the second conductive layer 62 may be formed by, for example, electroplating, chemical vapor deposition (CVD), sputtering, resistance heating evaporation, electron beam evaporation, other suitable deposition methods, or combinations of the foregoing, but the present disclosure is not limited thereto.

In some embodiments, the first conductive layer 30 may have a third thickness T3 in the second direction D2. As shown in FIG. 11, the third thickness T3 of the first conductive layer 30 may be between the bottom surface of the second conductive layer 62 and the top surface 20T of the first insulating layer 20. In some embodiments, the second conductive layer 62 may have a fourth thickness T4 in the second direction D2. As shown in FIG. 11, the fourth thickness T4 of the second conductive layer 62 may be the thickness of the second conductive layer 62 on the third insulating layer 50. In some embodiments, since the first conductive layer 30 may be serve as the conductive layer in a wafer level package (WLP) process, and the second conductive layer 62 may be serve as the conductive layer in panel level package (PLP) process, the fourth thickness T4 of the second conductive layer 62 may be greater than the third thickness T3 of the first conductive layer 30.

In some embodiments, the second conductive layer 62 may include a multi-layer structure, wherein the multi-layer structure may include a seed layer and a metal layer. For example, a seed layer (not shown) may be conformally formed on the top surface 50T of the third insulating layer 50 and the top surface of the second insulating layer 40, and in the second opening 42. Then, a metal layer (not shown) may be formed on the seed layer, so as to improve the reliability of the metal layer by the seed layer. In some embodiments, the seed layer and the metal layer may be formed by physical vapor deposition (PVD), electroplating, or other suitable formation processes, respectively, but the present disclosure is not limited thereto. In some embodiments, the seed layer may be a titanium copper alloy (TiCu), and the metal layer may include copper.

Referring to FIG. 12, it shows a schematic cross-sectional view of the second electronic device 2 in an intermediate manufacturing stage according to some embodiments of the present disclosure. In some embodiments, as shown in FIG. 12, a second photoresist 54 is formed on the first photoresist 52. Specifically, the second photoresist 54 may be formed on the top surfaces of the first photoresist 52 and the second conductive layer 62. In some embodiments, the material and formation method of the second photoresist 54 may be the same as or different from the material and formation method of the first photoresist 52. In some embodiments, the second photoresist 54 may be a dry film photoresist. In some embodiments, the second photoresist 54 may have openings 55 corresponding to the second conductive layer 62, to expose at least a portion of the top surface of the second conductive layer 62 by the openings 55 of the second photoresist 54.

Referring to FIG. 13, it shows a schematic cross-sectional view of the second electronic device 2 in an intermediate manufacturing stage according to some embodiments of the present disclosure. In some embodiments, the third conductive layer 64 may be disposed in the opening 55 of the second photoresist 54. In some embodiments, the material and formation method of the third conductive layer 64 may be the same as or different from the material and formation method of the second conductive layer 62. In some embodiments, the third conductive layer 64 and the second conductive layer 62 may have an interface. In other embodiments, the third conductive layer 64 and the second conductive layer 62 may substantially not have an interface. In some embodiments, the third conductive layer 64 may also include a seed layer and a metal layer, so that the reliability of the metal layer may be improved by the seed layer. In some embodiments, the thickness of the third conductive layer 64 may be greater than that of the second conductive layer 62 in the second direction D2.

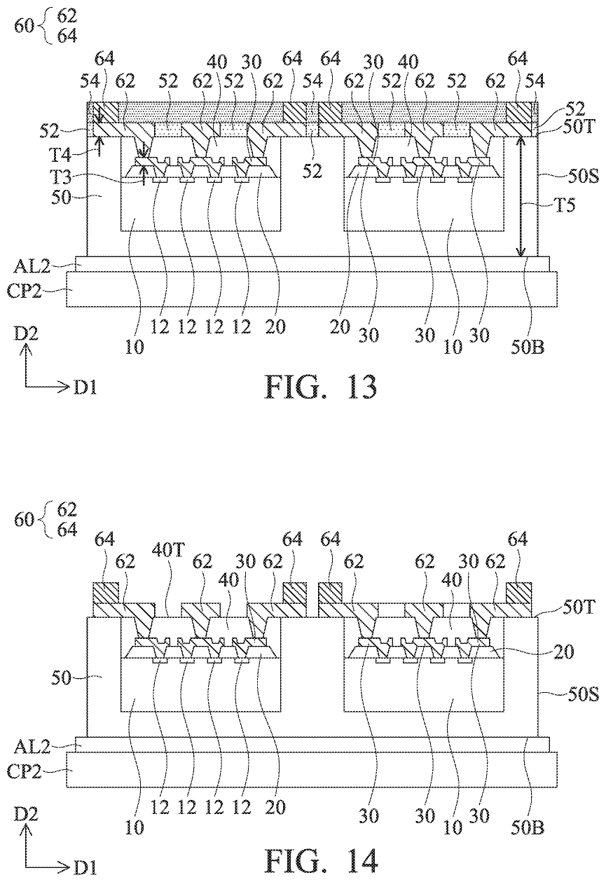

Referring to FIG. 14, it shows a schematic cross-sectional view of the second electronic device 2 in an intermediate manufacturing stage according to some embodiments of the present disclosure. In some embodiments, the second photoresist 54 and the first photoresist 52 may be removed, to expose the top surface 40T of the second insulating layer 40. In some embodiments, the second photoresist 54 and the first photoresist 52 may be removed by an ashing process, other suitable removal processes, or combinations of the foregoing, but the present disclosure is not limited thereto. In some embodiments, the second photoresist 54 and the first photoresist 52 may be removed in the same process. In other embodiments, the second photoresist 54 and the first photoresist 52 may be removed in different processes, respectively. In some embodiments, due to the selectivity ratio of the removal process, the removal process does not substantially damage the structures of the third conductive layer 64 and the second conductive layer 62.

In some embodiments, the third conductive layer 64 and the second conductive layer 62 may together serve as the connecting element 60 disposed on the second insulating layer 40. In other words, the connecting element 60 may include, for example, the second conductive layer 62 and the third conductive layer 64. In some embodiments, the connecting element 60 may be used as a redistribution element of the electronic device in the panel-level process. In some embodiments, the connecting element 60 may be connected to the bonding pad 12 of the electronic unit 10 through the first conductive layer 30. In some embodiments, since the third conductive layer 64 is in direct contact with and is electrically connected to the second conductive layer 62, the second conductive layer 62 is in direct contact with and is electrically connected to the first conductive layer 30, and the first conductive layer 30 is in direct contact with and is electrically connected to the bonding pads 12, the fan-out effects and/or the fan-out range may be effectively improved.

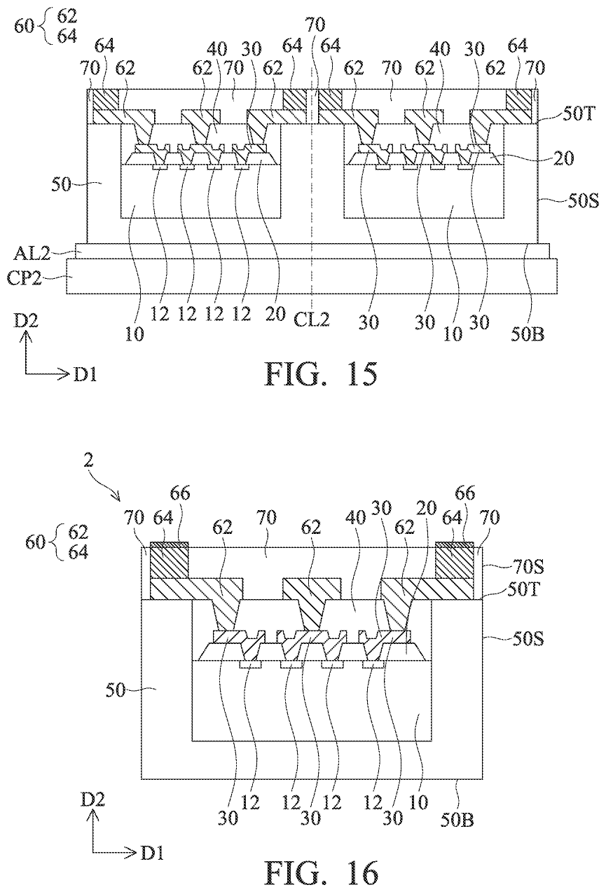

Referring to FIG. 15, it shows a schematic cross-sectional view of the second electronic device 2 in an intermediate manufacturing stage according to some embodiments of the present disclosure. In some embodiments, a fourth insulating layer 70 is provided on the connecting element 60, the third insulating layer 50 and the second insulating layer 40. In some embodiments, the fourth insulating layer 70 covers the side surface of the connecting element 60. In some embodiments, the fourth insulating layer 70 is in direct contact with the third insulating layer 50 and the second insulating layer 40. In some embodiments, the material and formation method of the fourth insulating layer 70 may be the same as or different from the material and formation method of the third insulating layer 50. In some embodiments, the fourth insulating layer 70 and the third insulating layer 50 may have an interface. In other embodiments, the fourth insulating layer 70 and the third insulating layer 50 may substantially not have an interface. In some embodiments, the hardness of the third insulating layer 50 and/or the fourth insulating layer 70 is different from that of the first insulating layer 20 and/or the second insulating layer 40. For example, the hardness of the third insulating layer 50 and/or the fourth insulating layer 70 may be greater than that of the first insulating layer 20 and/or the second insulating layer 40.

Then, in some embodiments, a second cutting process may be performed to separate the plurality of first electronic devices 1 into a plurality of second electronic devices 2. In some embodiments, the second cutting process and the first cutting process may be the same or different. As shown in FIG. 15, the second cutting process may be cut along a second virtual cutting line CL2.

In other embodiments, the fourth insulating layer 70 may include a first sub-insulating layer and a second sub-insulating layer formed in different processes. In this embodiment, following FIG. 9, a patterned first sub-insulating layer may be formed on the third insulating layer 50. Then, a second conductive layer 62 is formed in the opening of the first sub-insulating layer, and formed on the third insulating layer 50 and the second insulating layer 40. Then, a patterned second sub-insulating layer is formed on the patterned first sub-insulating layer. After that, the third conductive layer 64 is formed in the opening of the second sub-insulating layer, and the third conductive layer 64 is formed on the second conductive layer 62, thereby obtaining the connecting element 60.

Referring to FIG. 16, it shows a schematic cross-sectional view of the second electronic device 2 after performing the second cutting process according to some embodiments of the present disclosure. As shown in FIG. 16, in the first direction D1, the side surface 50S of the third insulating layer 50 of the second electronic device 2 may be aligned with the side surface 70S of the fourth insulating layer 70, so that the fourth insulating layer 70 and the third insulating layer 50 protects the electronic unit 10 of the second electronic device 2. As shown in FIG. 16, in some embodiments, bonding pads 66 may be further disposed on the third conductive layer 64. Therefore, the second electronic device 2 may be electrically connected to a printed circuit board (PCB) or other components through the bonding pads 66. In some embodiments, the material and formation method of the bonding pad 66 may be the same as or different from the material and formation method of the bonding pad 12. The fan-out effects and/or the fan-out range of the electronic device may be improved by disposing the redistribution layer of the second electronic device 2, wherein the redistribution layer is formed by stacking the second conductive layer 62, the third conductive layer 64 and the fourth insulating layer 70.

In conclusion, according to the embodiments of the present disclosure, an electronic device including a first insulating layer and a second insulating layer and a manufacturing method thereof are provided. By disposing insulating layers in stages, the problem of limited circuit design space that is insufficient to dispose element such as vias, wires, and redistribution layers may be avoided. In addition, the thickness ratio and/or material properties (for example, type of material, thermal expansion coefficient, warping direction) of the first insulating layer and the second insulating layer may be adjusted. Therefore, the fan-out effects and/or fan-out range of the electronic device may be improved, the compatibility with fine wire diameter process may be improved, the warping probability may be reduced, the reliability may be improved and/or the electrical performance may be improved. Furthermore, the electronic device and the manufacturing method thereof of the present disclosure may also be compatible with the chip first process and the redistribution layer first (RDL first) process.

avoid such as vias, wires, redistribution layers, etc. by disposing the insulating layers in stages The problem of cramped circuit design space. In addition, by adjusting the thickness ratio and/or material properties of the first insulating layer and the second insulating layer (e.g., material type, thermal expansion coefficient, warping direction), the fan-out effects of the electronic device may be improved and/or fan-out range, improve compatibility with fine wire diameter process, reduce warping probability, improve reliability and/or improve electrical performance. Furthermore, the electronic device and the manufacturing method thereof of the present disclosure may also be compatible with the wafer-first process and the redistribution-layer-first process.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the above-mentioned process, machine, manufacturing, material composition, device, method, and steps. It is not necessary for any embodiment or claim of the present disclosure to achieve all of the objects, advantages and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
an electronic unit, comprising a first surface, a second surface opposite to the first surface, and a first side surface connecting the first surface to the second surface;
a first insulating layer disposed on the second surface;
a second insulating layer disposed on the first insulating layer and comprising a third surface, a fourth surface opposite to the third surface, and a second side surface connecting the third surface to the fourth surface; and
a connecting element disposed on the second insulating layer and electrically connected to the electronic unit,
wherein the third surface of the second insulating layer is in contact with the second surface of the electronic unit.

2. The electronic device as claimed in claim 1, wherein the first insulating layer comprises a plurality of first openings, the second insulating layer comprises a plurality of second openings, and an angle of one of the first openings is different from an angle of one of the second openings.

3. The electronic device as claimed in claim 2, further comprising:
a first conductive layer disposed between the first insulating layer and the second insulating layer, and wherein the first conductive layer is electrically connected to the electronic unit through one of the first openings.

4. The electronic device as claimed in claim 2, wherein a roughness of a sidewall of one of the first openings is less than a roughness of a sidewall of one of the second openings.

5. The electronic device as claimed in claim 2, wherein at least one of the first openings and at least one of the second openings do not overlap in a normal direction of the electronic unit.

6. The electronic device as claimed in claim 2, wherein at least one of the first openings and at least one of the second openings overlap in a normal direction of the electronic unit.

7. The electronic device as claimed in claim 1, wherein the second side surface of the second insulating layer is aligned with the first side surface of the electronic unit.

8. The electronic device as claimed in claim 1, wherein the first insulating layer has a third side surface, the third side surface and the second surface have an included angle, and the included angle is greater than or equal to 45 degrees and less than 90 degrees.

9. The electronic device as claimed in claim 8, wherein the second insulating layer is in contact with the third side surface of the first insulating layer.

10. The electronic device as claimed in claim 1, wherein the connecting element further comprises:
a second conductive layer electrically connected to the first conductive layer.

11. The electronic device as claimed in claim 10, wherein a thickness of the second conductive layer is greater than a thickness of the first conductive layer.

12. The electronic device as claimed in claim 10, further comprising:
a third insulating layer surrounding the electronic unit, wherein a portion of the second conductive layer is in contact with a surface of the third insulating layer.

13. The electronic device as claimed in claim 12, wherein a first thickness of the first insulating layer is less than a second thickness of the second insulating layer, and the second thickness of the second insulating layer is less than a third thickness of the three insulating layers.

14. The electronic device as claimed in claim 12, further comprising:
a fourth insulating layer disposed on the connecting element and being in contact with the second insulating layer and the third insulating layer.

15. The electronic device as claimed in claim 1, wherein thermal expansion coefficients of the first insulating layer and the second insulating layer are different.

16. The electronic device as claimed in claim 1, wherein the first insulating layer and the second insulating layer are reverse warping layers.

17. A method for manufacturing an electronic device, comprising:
providing a substrate, and wherein the substrate comprises a plurality of electronic units;
providing a first insulating layer on the substrate; and
providing a second insulating layer on the substrate,
wherein the second insulating layer is in contact with a portion of a surface of the substrate.

18. The method as claimed in claim 17, further comprising:
performing a first cutting process to cut the substrate to separate the plurality of electronic units into a plurality of first electronic devices, wherein the side surface of the electronic unit in one of the first electronic devices and a side surface of the second insulating layer are aligned.

19. The method as claimed in claim 18, further comprising:
providing the plurality of first electronic devices on a carrier board;
providing a third insulating layer on the plurality of first electronic devices;
providing a connecting element on the second insulating layer and on the third insulating layer;
providing a fourth insulating layer on the connecting element and the third insulating layer; and
performing a second cutting process to separate the plurality of first electronic devices into a plurality of second electronic devices.

20. The method as claimed in claim 17, wherein a surface of the second insulating layer is in contact with a surface of the plurality of electronic units.
